(19) United States
(12) Patent Application Publication
(10) Pub. No.: US 2008/0094453 A1
(43) Pub. Date: Apr. 24, 2008

(54) Inkjet Print Head

(75) Inventor: Frank W. Rohlfing, Cambridge (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/722,749

(22) PCT Filed: Jan. 3, 2006
(86) PCT No.: PCT/IB06/50010

§ 371 Date: Jun. 25, 2007

(30) Foreign Application Priority Data
Jan. 6, 2005 (GB) 0500114.4

(51) Int. Cl. B41J 2/14; B41J 2/05; H01L 21/00

(52) U.S. Cl. 347/59; 438/21; 257/E21.001

(57) ABSTRACT

An inkjet print head comprises an array of print head heater circuits, each associated with a respective print head nozzle. Each heater circuit comprises a heater arrangement (28) and a drive transistor (16) for driving current through the heater arrangement (28). The drive transistor (16) comprises a top gate polysilicon thin film transistor having a field relief doped region (20) beneath the gate, and the heater arrangement comprises a portion of the polysilicon layer which defines the drive transistor channel. This enables a heating resistor and driving thin film transistors (TFTs) (as well as control logic) to be fabricated on large, rectangular substrates using a poly-Si TFT technology.

This invention relates to thermal inkjet print heads, particularly to the drive circuitry associated with the individual print nozzles.

Thermal inkjet printing is a printing technique that is widely used. A typical inkjet printer contains at least one print cartridge in which small droplets of ink are formed and ejected towards paper or any other print medium to form an image on the medium. The part of the cartridge that is closest to the print medium is often referred to as the print head. It contains an orifice plate into which an array of tiny nozzles is drilled. There is an ink chamber adjacent to each nozzle in which ink is stored prior to droplet formation. Each ink chamber is equipped with an ohmic resistor that creates heat. Ink ejection is accomplished by rapidly heating the ink stored in the chamber. The rapid expansion of the ink vapour forces a portion of the ink in the chamber through the nozzle in the form of a droplet. The collapsing bubble creates a vacuum in the chamber, which results in refilling of the chamber with ink from an ink reservoir within the cartridge, with which all chambers are in fluid communication. The replenished ink cools the resistor, the chamber walls and the nozzles, so that refilling and cooling prepares them for the next droplet to form when the heating resistor is next activated.

The resistor is deposited in thin-film form on a silicon substrate or any other substrate, and the resistive material used is typically a metal alloy. In order to avoid chemical reactions between the resistor and the ink (which in most applications is water based), the resistor and its metal terminals are covered by at least one inert and heat resistant passivation layer, which often consists of silicon nitride. A cavitation layer may be deposited on top of the passivation layer to reduce mechanical damage to the passivation and the resistor layers, which may occur as a result of the impact from the ink that enters the chamber when it refills after droplet ejection.

The resistor is connected to a drive transistor that switches it on and off in a particular sequence depending on the data to be printed. The drive transistor is adjacent to the resistor and it is fabricated on the same substrate as the resistor. A number of different technologies can be used to form the drive transistor. The channel of the transistor has to be sufficiently wide so that its resistance in the on state is small compared to the resistance of the heating resistor.

In order to deliver high print throughput and high print resolution, modern print heads typically have a nozzle count of several hundred and a nozzle pitch of 20-100 μm. The combination of high nozzle count and small pitch makes it impractical to address switching transistor individually with external logic circuitry, as this would require one contact pad for each nozzle. Therefore, modern print heads have logic circuitry embedded on the print head substrate which is fabricated in the same process as the switching transistors. The integrated logic circuitry has a single, serial print data input and thereby dramatically reduces the number of external contact pads.

There are a number of difficulties and problems associated with the fabrication of ink jet print heads.

Although the nozzle count of inkjet cartridges has increased dramatically over the last few years, nozzle array dimensions are still much smaller than the dimension of a typical print medium. For example, the dimensions of the nozzle array in a standard print cartridge for office applications is approximately 10-20 times smaller than the width of A4 and B4 paper. To compensate for this discrepancy in dimensions, inkjet printers are equipped with a computer-controlled transport mechanism including a stepping motor which achieves full coverage of the print medium by moving the cartridge across it in a serpentine fashion. The availability of a print head whose nozzle array dimension is equal to that of the print medium would eliminate the need of a cartridge transport mechanism. This would simplify the printing process and it would also increase print throughput because of the high nozzle count of such a print head.

Conventional print heads are fabricated on silicon wafers. The maximum diameter of commercial silicon wafers is 30 cm. Hence, in a production process based on 30 cm wafers, only the centre section can be used to fabricate a print head whose nozzle array dimension equals that of a typical print medium (A4 or B4 paper). The majority of the active wafer area would not be suitable for page-wide print heads. In principle, there is the possibility to fabricate individual sections of a print head and subsequently connect these to a page-wide print head, but this is technically difficult, expensive and it results in image artifacts, which are associated to the quality of the connection between adjacent print head sections.

For advanced print heads with very high nozzle counts, poly-crystalline silicon (poly-Si) thin-film transistor (TFT) technology has been proposed. In poly-Si print heads, poly-Si islands provide the channel, source, drain and field-relief regions. They are formed by depositing amorphous silicon (a-Si) via chemical vapour deposition (CVD) on a substrate, followed by dopant implantation and crystallisation of the a-Si with a laser or other crystallisation techniques known in this field. As the substrate is not part of the TFT but merely provides mechanical support, a wide range of substrate materials can be used such as glass, plastic foils or steel foils. The processing can use larger rectangular substrates, which are more suitable for print head applications.

A problem with the use of poly-Si technology relates to the high power required for droplet ejection. The channel of the firing transistor has to be sufficiently wide so that the voltage V_{DD} drops almost entirely across the heater when the gate is high. Ideally, the on resistance of the transistor should not be more than 10% of the resistance of the heater. For some printing applications, the power required for droplet formation can be as high as 2 Watts per nozzle. Given that the nozzle pitch for most applications is only of the order of 20 to 200 μm, the power per nozzle is very high. This power requires the use of a very wide transistor, and one of the key issues with thermal inkjet printing is to fit such a transistor into a small nozzle pitch. This is particularly the case for print heads in which the driving transistor is made using poly-Si technology rather than conventional CMOS technology on silicon wavers. This is because poly-Si TFTs have a higher threshold voltage and a lower mobility and therefore deliver a lower current per channel width than conventional CMOS transistors.

One way of reducing the required channel width is to increase the voltage V_{DD}. In order to keep the power constant, the resistance of the heater has to be increased as well, and this means that a transistor with a smaller width will be sufficient to guarantee that its on-resistance is still small compared to the resistance of the heater. As the resistance of the heater scales quadratically with the voltage V_{DD} for fixed power, the required transistor width reduces with the inverse of the square of V_{DD}. Hence, increasing V_{DD} is a very effective way to ensure that the transistor fits to a small nozzle pitch. This is particularly important for the use of poly-Si TFT to drive the nozzles.

However, whilst increasing V_{DD} reduces the size of the transistor, it also reduces its lifetime as the higher voltage drop across the channel results in transistor degradation due to avalanching, hot-carrier effects and self-heating. Conventional poly-Si TFTs as used for active-matrix liquid-crystal displays or organic electroluminescent displays can tolerate a maximum source-drain voltage in the off state of typically 10V without electrical degradation during their required lifetime. TFTs used for the above display applications normally have low-dose field-relief regions outside and self-aligned to the gate to reduce parasitic gate-source and gate-drain capacitances.

A further problem relates to degradation of the heat chamber. Firing chamber designs in which the entire active area of the heating resistor is located fully inside the chamber use the dissipated heat most effectively, as such a design avoids an excessive temperature increase of the chamber walls and in neighbouring firing chambers. In conventional designs this is accomplished with a resistive layer that extends beyond the firing chamber and conducting metal traces deposited on top of the resistive layer that terminate inside the firing chamber close to the firing walls. A passivation and a cavitation layer are deposited on top of the resistive layer and the metal traces. Hence, a conventional design has two abrupt steps within the firing chamber layers at the position where the two metal traces terminate. It is well known in the field of inkjet printing that these steps are prone to degradation due to constant temperature cycling during printing and due to the momentum caused by ink refilling the chamber after droplet ejection.

According to the invention, there is provided an inkjet print head comprising an array of print head heater circuits, each associated with a respective print head nozzle, wherein each heater circuit comprises a heater arrangement and a drive transistor for driving current through the heater arrangement, wherein the drive transistor comprises a top gate polysilicon thin film transistor having a field relief doped region beneath the gate, and wherein the heater arrangement comprises a portion of the polysilicon layer which defines the transistor channel.

This device enables a heating resistor and driving thin film transistors (TFTs) (as well as control logic) and the electrical connections between these to be fabricated on large, rectangular substrates using a poly-Si TFT technology. In current poly-Si mass production facilities, the substrates used are typically glass sheets with a size ranging between 0.5 and 2 m². This enables the production of page-wide print heads, and as the substrates are rectangular rather than round as in a conventional silicon wafer process, the entire substrate area is available for print head fabrication.

The switching TFT is based on an architecture with an implanted field-relief region (preferably low dose), underneath the gate, preferably adjacent to a high-dose implanted drain region. This architecture is referred to as gate overlapped lightly doped drain (GOLDD) architecture. Compared to conventional field-relief architectures, the use of GOLDD results in a dramatic improvement in maximum tolerable source-drain voltage in the off state. For a comparable oxide thickness, channel length and mobility as conventional architectures, GOLDD TFTs can tolerate a source-drain voltage of approximately 30V in the off state. Given the quadratic dependence between channel width and supply voltage V_{DD}, and using the above values of 10V and 30V, the use of GOLDD reduces the channel width by a factor of approximately 9. This is a key advantage of the use of this GOLDD architecture for thermal inkjet printing.

As mentioned above, the power per nozzle is typically as high as 2 Watts. If conventional TFTs are used, with a maximum voltage of approximately 10V, the TFT channel would need to be 2-3 cm wide, assuming typical TFT parameters (channel length, mobility etc). It is extremely difficult to adapt TFTs with a width of 2-3 cm to a pitch of 20-200 um as required for current print applications. However, the use of GOLDD devices enables the channel width to be reduced to approximately 2-3 mm. Preferably, the channel width of the transistor is less than 5 mm.

By fabricating the heating arrangement using the polysilicon layer of the transistor, it is possible to eliminate abrupt steps within the firing chamber as the resistor and its terminals are fabricated in the same layer, resulting in a coplanar structure. This improves yield and enables the use of thinner passivation and cavitation layers, which in turn reduces the energy necessary for droplet formation. In an important embodiment of this invention, the region of the poly-Si island within the firing chamber is lightly doped to form the heating resistor and the adjacent regions are heavily doped to form the resistor terminals.

Preferably, the heater arrangement comprises doped terminal portions and a heating portion between the terminal portions, formed from the same layer.

There are then no constraints as to the location of the junctions between the resistor and its terminals relative to the location of heating chamber walls, as these junctions can simply be determined by different implant regions within the poly-Si island. Hence, the resistor boundary can be as close as possible to the chamber walls. In conventional firing chamber designs, minimum spacing and other design rules apply between the chamber walls and the abrupt steps caused by the metal traces overlapping the resistive layer.

This also enables any steps to be avoided in the firing chamber, as the terminal portions can extend from the heating portion to an area outside the footprint of the firing chamber, and the connections to the terminal portions are then outside the firing chamber footprint.

A number of doping operations can be shared between the transistor fabrication and the heating arrangement fabrication.

For example, the same doping can be applied to the polysilicon layer to define the field relief region and the heating portion. The terminal portions can also be doped, with different doping to the heating portion. The same doping can then be applied to the terminal portions as to source and drain contact portions of the drive transistor.

A metal contact layer preferably connects to the source and drain contact portions and to the heating arrangement. This layer can extend into an area beneath the heating chamber, and this enables the heating arrangement to comprise a polysilicon island with uniform doping.

The drive transistor may have multiple field relief regions, for example one adjacent each of the source and drain, or multiple regions of different doping adjacent the drain. The latter option enables the pitch to be reduced further. Both options give different possible processing steps.

The transistor may comprise a self-aligned or non self-aligned thin film transistor.

The invention also provides a method of fabricating an array of print head heater circuits for an inkjet print head, the circuits provided over a common substrate, the method comprising:

providing a dielectric layer over the common substrate;

depositing an amorphous silicon layer over the dielectric layer;

processing the amorphous silicon layer to form polycrystalline portions;

providing a gate dielectric layer over the doped polysilicon layer;

providing a gate conductor layer over the gate dielectric layer and defining at least gate terminals from the gate conductor layer; and

providing a further dielectric layer,

wherein a plurality of doping operations are performed to define source, gate, drain and field relief transistor regions in the polysilicon portions, a field relief region being provided at least adjacent the drain transistor region beneath the gate, and wherein the heater arrangement comprises a portion of the polysilicon layer which defines the drive transistor channel.

Examples of the invention will now be described in detail with reference to the accompanying drawings, in which:

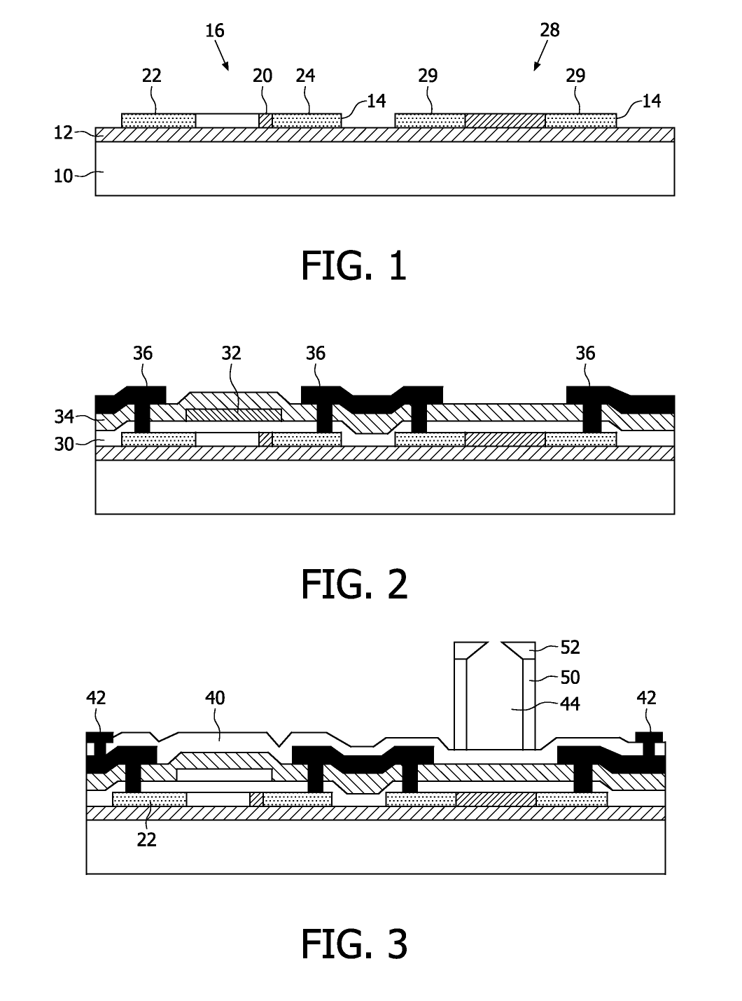

FIGS. 1 to 3 show the process used to make a first example of print head of the invention;

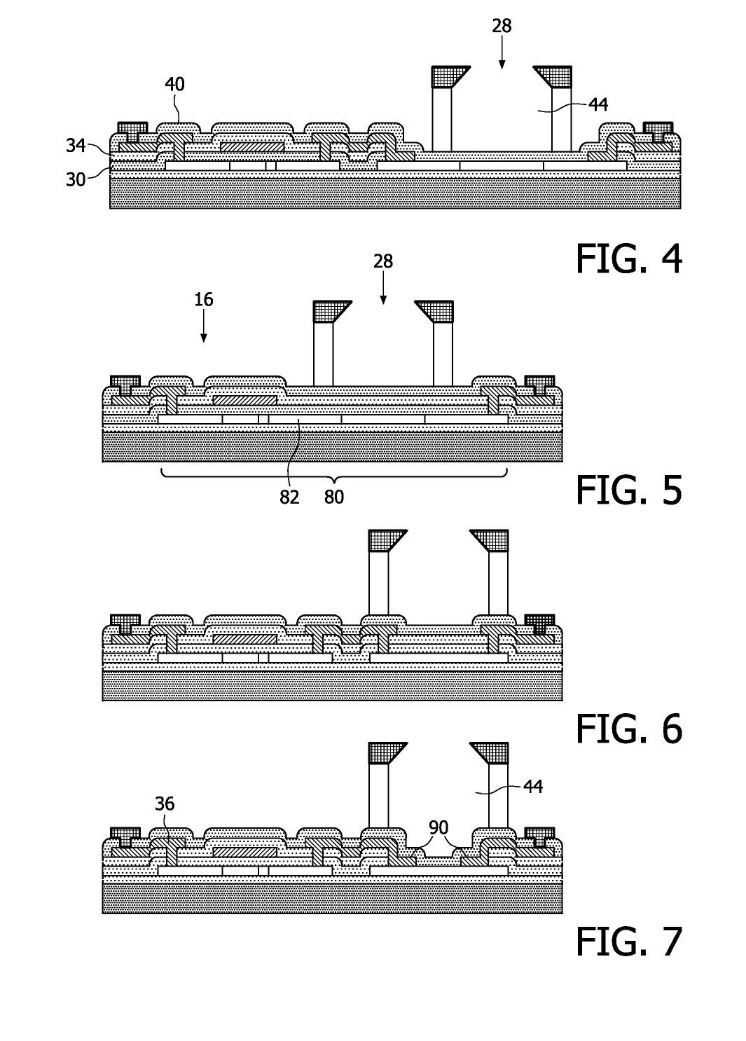

FIGS. 4 to 10 show further examples of print head of the invention.

The invention provides an inkjet print head heater circuit which uses a top gate polysilicon thin film transistor having a field relief doped region beneath the gate. A portion of the polysilicon transistor layer forms the heater.

This enables the fabrication of thermal inkjet print heads with a high nozzle count to enable page-wide printing and a small nozzle pitch for high print resolution. The former is made possible because of the use of a poly-Si TFT process which is compatible with large rectangular substrates, and the latter is made possible due to the use of the particular transistor architecture with improved maximum operating voltage. These can deliver the same power as conventional poly-Si TFTs, but with a dramatically reduced channel width.

Abrupt steps in the layers inside the firing chamber can be avoided as the resistor and its terminals can be defined in the same poly-Si island through regions with different implant doses. The absence of abrupt steps in the chamber improves yield and allows the use of thinner passivation layers. Furthermore, separate process steps can be avoided for the fabrication of the resistive heater, its metal connections, and thermal insulation, passivation and cavitation layers. All these can use steps from the poly-Si TFT process flow.

The heater circuit for an ink jet print head nozzle comprises a thin film transistor and a heating arrangement in series between power supply lines. FIGS. 1 to 3 show the process flow for one preferred embodiment of the invention, and the transistor is shown generally as 16 and the heater generally as 28. This embodiment is based on a non-self aligned n-type TFT architecture whose field-relief region is fully overlapped by the gate. FIGS. 1 to 3 show progressive stages in the fabrication process, and for simplicity, reference numbers for features which appear in different Figures are generally not repeated.

In a poly-Si process the substrate 10 merely provides mechanical support for the poly-Si circuitry. Unlike conventional Si wafer processes, it does not form any part of the transistors. A range of substrates can therefore be used, like glass, plastic foils or metal foils. In poly-Si mass production processes for display applications, glass sheets with a thickness of typically 0.4 mm and a size between 0.5 and 2 m² are used.

The process starts with an initial clean of the substrate 10, followed by the deposition of a stack of dielectric layers (not shown) on the back of the substrate, typically SiNx and SiOx. The main reason for depositing dielectrics on the back as well as the front is that HF, which is used as etchant in the process, also etches glass, which results in pitting. Another reason is that impurities within the substrate could contaminate the etch baths. For very thin substrates, the deposition of a dielectric stack on the back compensates for mechanical stress due to the layers deposited on the front.

After depositing on the back of the substrate, a stack of dielectric layers 12 is deposited on the front, typically SiOx on top of SiNx, followed by an a-Si layer 14 with a thickness of typically 20-100 nm. The hydrogen content of the a-Si film is reduced to typically 3% through a thermal anneal at typically 450° C. The nitride layer prevents diffusion of components (e.g. B, P, Na) from the substrate into the deposited layers, in particular into the poly-Si islands that form the TFTs. Impurities in the TFT channel will affect the electrical performance of the TFT. In particular, B and P will shift the threshold voltage. The dual layer of SiNx and SiOx reduces the pinhole density to the substrate.

Photo resist is spun on top of the a-Si layer, into which features are defined photo lithographically to form islands for fabrication of the heating resistor 28 and drive TFT 16, and any other n-type or p-type TFTs, resistors, capacitors, MOS capacitors or conductive traces that are required for the logic circuitry integrated on the same substrate to distribute print data to the firing TFT gates. The a-Si features can be dry etched using RIE with a SF₆/HCL/O₂ gas mixture, but other etching techniques are also available to those skilled in this field.

After island definition, the TFTs need a low-dose boron implant of typically 1-3×10¹² cm⁻² to adjust their threshold voltage. However, for low levels of contamination this step may be omitted. The dopant concentration required to optimise the threshold voltage of n- and p-type TFTs may not be identical. If this is the case, a blanket implant is applied in addition to a patterned implant.

Further mask definitions and ion implantations are needed for the source 22, drain 24 and field-relief regions 20 of the firing TFTs and any n- and p-channel TFTs in the integrated logic circuitry, the resistor and its two terminals as well as for any capacitors, MOS capacitors or conducting traces made of doped poly-Si that the logic may use.

The TFT field-relief region 20 requires a phosphorus dose between 3×10¹² and 3×10¹³ cm⁻² (typically 9×10¹² cm⁻²) to prevent TFT degradation and the source and the drain dose is typically 10¹⁵ cm⁻².

The same dose but with boron as the implant species is required for the source and drain region of p-channel devices.

In a preferred embodiment of this invention, which reduces the number of ion implantation and photo lithographic steps, the poly-Si regions forming the resistor terminals 29 are doped in the same high-dose implantation step as the source and the drain contact regions of p-channel or the n-channel TFTs (source 22 and drain 24). The advantage of this is that no additional process steps are necessary for the heat transducer, which greatly simplifies the process flow and increases production yield.

The resistance of the heating resistor is determined by, amongst other factors, the energy needed for droplet formation and the maximum voltage V_{DD} that will be applied to the resistor. The required value can be tuned by changing resistor length, width, thickness and sheet resistance, the latter of which can be adjusted by changing the implant dose in this region. A preferred embodiment of this invention avoids the use of a separate ion implantation step for the resistor. Instead, the resistor 28 is doped in the same implantation step as the field-relief regions 20 or any other suitable implantation step available within the process.

The resistor has lower resistance terminals 29 and a central heating part.

After ion implantation steps, resist removal and surface clean, the implanted a-Si islands are converted into poly-Si islands with an excimer laser beam with an energy density of typically 300 mJ/cm², or any other laser beam suitable for laser crystallisation. Alternatively, other crystallisation techniques can be used that are known in this field such as metal-induced laser crystallisation or sequential lateral solidification.

FIG. 2 shows the gate oxide 30. Its thickness may range between 20 and 150 nm and it may be deposited via CVD, following a thorough surface clean of the crystallised Si islands. The oxide also functions as a passivation layer in the firing chamber.

A gate metal 32 is deposited on top of the gate oxide. An aluminium alloy with a typical thickness of 200 to 300 nm may be used as gate metal, and the metal can be defined using dry or wet etching. In the following step, an interlayer dielectric 34 is deposited on top of the gate metal via CVD. SiNx may be used and a typical thickness for a 200-300 nm gate metal would be 500 nm. This layer also functions as a passivation layer in the firing chamber.

Contact holes to the source and drain, the resistor terminals and to the gate metal are opened via wet or dry etch techniques. This requires etching through the dielectric layer 34 to connect to the gate metal, and etching through the dielectric 34 and the gate oxide 30 to connect to source, drain and resistor terminals. The connection to the gate metal is not shown in the Figures.

Depending on process details, a different technique may be needed to open contacts to the gate metal than is used to open contact windows to implanted poly-Si. A second metal layer 36 is deposited and defined into conducting traces via photolithography and wet or dry etching.

FIG. 3 shows the dielectric layer 40 that is deposited on top of the source/drain metal 36 to allow another (third) metal layer 42 to be used for routing. This dielectric layer 40 also functions as passivation and cavitation layer in the firing chamber 44. Contact holes are opened in this layer via dry or wet etch to terminate on top of the source/drain metal. The third metal layer 42 is deposited and defined photolithographically to connect to the source 22 of the firing TFT and to one terminal of the heating resistor. This metal is also used for higher-level routing within the integrated logic circuit.

In final process steps shown in FIG. 3, the material 50 for the firing chamber walls is deposited and the walls are defined such that the heating resistor is located inside the firing chamber. An orifice plate 52 is bonded on top of the chambers.

The invention thus provides a thin-film transistor (TFT) with a source, a drain and a gate. The poly-crystalline silicon (poly-Si) island that provides the channel, source and drain, is formed by depositing amorphous silicon (a-Si) via chemical vapour deposition (CVD) on a substrate and subsequent crystallisation of the a-Si with a laser or other crystallisation techniques known in this field. As the substrate is not part of the TFT but merely provides mechanical support, a wide range of substrate materials can be used such as glass, plastic foils or steel foils. Gate oxide and gate metal are fabricated on top of the poly-Si island. In addition to the high dose implant regions forming the source and drain regions, the TFT has a low-dose implant region adjacent to the drain and overlapped by the gate. This region reduces the drain electric field and thereby allows the application of a higher voltage across the channel without compromising TFT stability and avalanche current. The source of the TFT is connected to ground and the drain is connected through a metal interconnect to one terminal 29 of the poly-Si resistive heater that is fabricated in the same process step as the poly-Si island forming the TFT. The second terminal 29 of the resistor is connected via a metal interconnect to a supply voltage. A passivation layer covers TFT and resistor, and an ink chamber is defined on top of the resistor.

If the TFT is an n-type transistor as in FIG. 3, the TFT will be in the on state if the gate is high. Provided its on resistance is small compared to the heater resistance, the external voltage V_{DD} will drop almost entirely across the resistor, which will result in ink evaporation and droplet ejection. If the gate signal is low, the TFT is in the non-conducting state. There will be no heat dissipation in the resistor and the external voltage V_{DD} will drop almost entirely across the TFT channel. In case a p-type transistor is used, the resistor will dissipate heat if the gate voltage is low and there will be no heat dissipation if the gate voltage is high.

If the substrate is a good thermal conductor like a steel foil or a Si wafer, it is important to thermally isolate the heater from the substrate so that the amount of energy that is transferred into the substrate rather than to the ink in the chamber is minimised. The dielectric capping layer also functions as thermal insulation layer for the resistor, which eliminates the need for separate depositions and masks for the fabrication of the insulation layer.

The process of the invention also provides efficient use of the different material layers of the TFT structure for the resistor fabrication. In particular, several dielectric layers are required in a poly-Si TFT processes and these include the gate oxide, a dielectric layer between gate and source/drain metal, a dielectric layer on top of the source/drain metal and for the most commonly used substrates like glass, plastic or steel foils, a capping layer between the substrate and poly-Si. The latter is required to prevent impurities to migrate from the substrate into poly-Si, where these would degrade the electrical properties of the TFTs, and to insulate the substrate from the poly-Si in case conducting substrates are used. Often silicon oxide is chosen as the capping layer, or the top capping layer if more than one layer is used, as its high-quality interface to poly-Si gives the best electrical TFT properties.

The gate oxide and the two dielectric layers required for the TFTs can also function as passivation and cavitation layers for the poly-Si resistor. Hence, no separate process steps such as depositions and photolithographic mask steps are required for the fabrication of these layers.

The gate oxide is thicker in poly-Si TFT processes compared to conventional Si processes. This is because the oxide has to be deposited and cannot be grown thermally as this would melt the substrate. Furthermore, the rough surface of the poly-Si layer, which consists of randomly orientated Si crystals of different sizes, requires a thick oxide to prevent short circuits between gate metal and poly-Si. Because of its increased thickness, the gate oxide makes a significant contribution to the overall thickness of the passivation layers. In conventional Si processes, the oxide thickness is only a few nanometers, which is far too thin to protect the resistor and therefore requires the deposition of a separate thick passivation layer. The advantage of three layers functioning as passivation layers is that this reduces the effective pinhole density resulting in better yield. However, for some applications the use of the top dielectric layer may be sufficient, in which case the gate oxide and the dielectric on top of the gate metal can be removed in the same process step as the contact hole opening.

Hence, no process steps specific to the fabrication of the heating elements are required, as the insulation layer, the resistor as well as the passivation layer are all formed as part of the poly-Si TFT process.

In another embodiment of this invention illustrated in FIG. 4, the gate oxide 30 and the dielectric 34 on top of the gate metal are removed in the poly-Si resistor area 28, leaving only the top dielectric layer 40, which may consists of multiple layers, to function as passivation and cavitation layer. The gate oxide 30 and the dielectric layer in the resistor are cleared in the same process as the contact window openings to the doped poly-Si. The difference to the embodiment shown in FIG. 3 is that the source/drain metal needs to be removed in areas where the metal is on top of a dielectric and in the resistor area where it covers implanted poly-Si. Etch techniques are known to those skilled in the art that allow metal to be removed in both areas with the same process steps. The advantage of this embodiment is that it offers an opportunity to reduce the overall thickness of the passivation and cavitation layers compared to the embodiment shown in FIG. 3. This enables droplet formation at a lower thermal energy.

In yet another embodiment of this invention shown in FIG. 5, the firing transistor and resistor use the same poly-Si island 80. In particular, a heavily-doped, highly-conducting region 82 is fabricated within that island via photolithography and ion implantation which functions both as TFT source region and as the resistor terminal electrically connected to the TFT source. The advantage of this embodiment is that it reduces the layout area due to the absence of a connecting metal trace compared to the embodiment in FIG. 3. The reduced layout area enables a smaller nozzle pitch for high-resolution print applications.

The sheet resistance of heavily doped poly-Si is typically 200 Ohm/square, and this value is much higher than the sheet resistance of metal, which is approximately 0.1 Ohm/square for aluminium or aluminium alloys. Hence, the poly-Si connection in FIG. 5 will add significant series resistance compared to the metal connection in FIG. 3. However, because of the use of highly stable GOLDD TFTs, the required power per nozzle can be accomplished with a high value for V_{DD} so that a heating resistor with a high resistance can be used. Hence, any additional series resistance, which may be introduced by combing TFT source and resistor terminal in one poly-Si region compared to the low resistance arrangement in FIG. 3, can be kept small compared to the resistance of the heater due to the use of GOLDD TFTs that can be operated at high voltages.

FIGS. 6 and 7 show further embodiments of the invention, where the heating resistor is connected to the source of the firing TFT and the external supply voltage V_{DD} via metal traces 90 defined in the source/drain metal 36 that reach into the firing chamber 44 and terminate close to the chamber walls. In FIG. 6, the gate oxide and two dielectric layers function as passivation and cavitation layers, and in FIG. 7, the gate oxide and the first dielectric layer are removed in the same way as in FIG. 4. The advantage of these two embodiments is that they slightly reduce the layout area. The disadvantage is the presence of an abrupt step in the firing chamber, which is prone to degradation as described above.

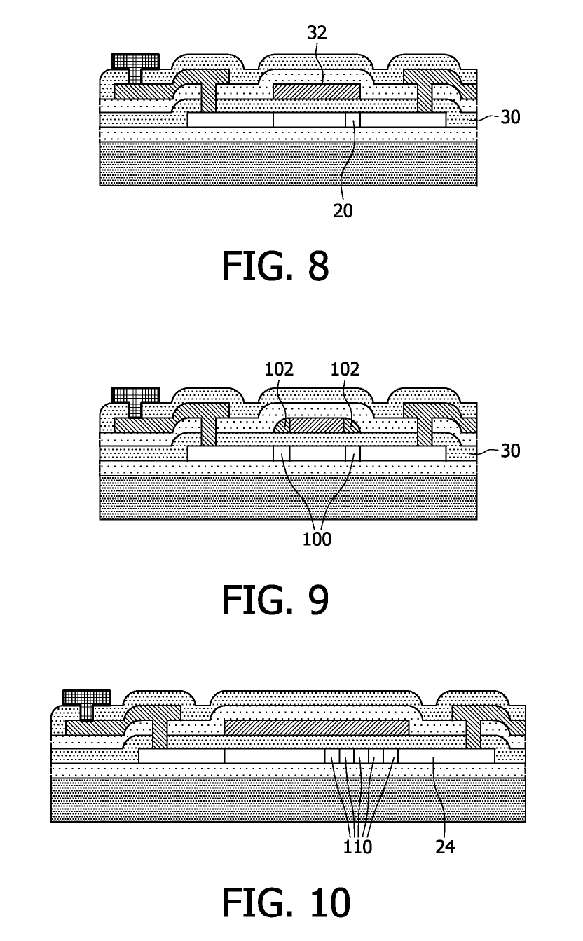

The embodiments in FIGS. 1 to 7 are based on a non-self-aligned (NSA) GOLDD process. Other GOLDD architectures exist and examples are shown in FIGS. 8 and 9. Their use as firing TFTs and in integrated logic circuitry for thermal inkjet applications is also intended to be within the scope of this invention. The Figures only show the TFT part of the heater circuit, as the change in architecture does not affect the heating resistor and the firing chamber.

FIG. 8 shows a self-aligned (SA) GOLDD TFT, where the gate is used as a mask to align the source and drain doped regions of the polysilicon TFT island to the edge of the gate. In a typical SA GOLDD process, low dose regions for threshold voltage adjustment and field relief regions are implanted first, followed by crystallisation of the Si islands. A gate oxide is then deposited, followed by gate metal deposition and definition. Source and drain regions are implanted preferably through the gate oxide, or after gate oxide removal at lower implant energy, using the gate as a mask.

The option of removing the gate oxide from regions other than beneath the gate is not shown in the drawings, but this is an option which enables a lower implant dose to be used. This does, however, require an extra process step.

As the source and drain implantation damages the poly-crystalline structure in these regions, a laser or thermal anneal is required to re-crystallise these regions.

The advantage of a SA process compared to the non-self-aligned (NSA) process above is that it produces smaller TFTs and reduces gate-source and gate-drain parasitic capacitances due to the absence of source and drain overlap. The former reduces the nozzle pitch and the latter improves the operating frequency in the logic circuitry. The disadvantage is a reduction in the maximum operating voltage V_{DD} due to lower stability of SA GOLDD TFTs. The reason for the reduced stability is that SA GOLDD TFTs have a higher electric field at the drain because of the abrupt change in the doping profile at the junction between drain and field-relief region 20. The NSA architecture described above is characterised by broadened junctions between channel and field-relief region and between field-relief region and drain as a result of the dopant diffusion in the molten Si during laser crystallisation. The broadened junctions reduce the field at the drain and thereby allow a higher voltage across the channel without degradation. In a SA GOLDD architecture, as depicted in FIG. 8, there will be no dopant diffusion at the junction between drain and field-relief region as this junction is partly covered by the gate which is reflective and thereby prevents melting of the Si at the junction during re-crystallisation.

The embodiment in FIG. 9 is based on a fully SA GOLDD architecture where the field relief-regions 100 are defined using a conducting spacer. After gate definition, field-relief regions are implanted through the oxide 30 using the gate as the mask. After fabrication of a conducting spacer 102, the source and drain regions are implanted. A thermal anneal re-crystallises the silicon. The advantage of this architecture is that it is even smaller than the SA GOLDD architecture in FIG. 8, but the disadvantage is that the maximum source drain voltage is reduced even further as both junction have an abrupt doping profile.

FIG. 10 shows yet another embodiment. As in FIGS. 1-7, the firing TFT is based on a NSA GOLDD architecture. The only difference is that the architecture has multiple field-relief regions 110 at the drain, each of which is characterised by a certain implant dose and length. At least one of the field-relief regions may not receive an implant during field-relief region fabrication. In this case its implant dose will be either identical to the dose required for threshold voltage adjustment, as this dose is normally applied to the entire poly-Si island forming the TFT, or zero if the level of contamination is sufficiently low such that threshold voltage adjustment is not required. In a preferred embodiment, the implantation dose of a field-relief region is higher the closer the region is located to the drain.

The advantage of multiple field-relief regions is that they reduce the electric field at the drain, resulting in reduced kink effect, avalanche current and electric-filed induced leakage current. Hence, GOLDD devices with multiple field-relief regions enable a higher operating voltage V_{DD} without compromising stability. For fixed power per nozzle, the use of a higher V_{DD} means that the resistance of the heater can be increased as well. Hence, a TFT with a smaller width will be sufficient to guarantee that its on-resistance is still small compared to the resistance of the heater. As the resistance of the heater scales quadratically with the voltage V_{DD} for fixed power, the required TFT width reduces with the inverse of the square of V_{DD}. Hence, the introduction of multiple field relief regions is a very effective way to reduce nozzle pitch.

GOLDD, in particular GOLDD with multiple field-relief regions have a key advantage for printing applications with wide or page-wide nozzle arrays. The series resistance introduced by metal traces that connect all firing TFT sources and resistors to common ground or V_{DD}, respectively, is large in wide arrays with large nozzle counts. In order to ensure that the voltage V_{DD} drops almost entirely across the resistor, the series resistance of the source traces has to be small compared to the TFT on resistance and the series resistance of the resistor traces has to be small compared to the heater resistance, the former would otherwise reduce the gate source voltage, which would in turn increases the TFT on resistance, and the latter would reduce the voltage at the resistor terminals. For circuits based on GOLDD or GOLDD with multiple field-relief regions, the series resistance due to connecting traces is much smaller than the TFT on resistance and the heater resistance compared to circuits with conventional TFTs that cannot be operated at high V_{DD}.

GOLDD TFTs with multiple field-relief regions can also be fabricated in a SA and fully self aligned process as described in FIGS. 8 and 9, respectively.

Various modifications will be apparent to those skilled in the art.

1. An inkjet print head comprising an array of print head heater circuits, each associated with a respective print head nozzle, wherein each heater circuit comprises a heater arrangement (28) and a drive transistor (16) for driving current through the heater arrangement (28), wherein the drive transistor (16) comprises a top gate polysilicon thin film transistor having a field relief doped region (20) beneath the gate, and wherein the heater arrangement comprises a portion of the polysilicon layer which defines the drive transistor channel.

2. A print head as claimed in claim 1, wherein the field relief region (20) is provided between a drain contact region (24) and channel of the drive transistor (16).

3. A print head as claimed in claim 1, wherein the heater arrangement comprises doped terminal portions (29) and a heating portion between the terminal portions (29), formed from the same layer.

4. A print head as claimed in claim 3, wherein the polysilicon of the drive transistor (16) and heater arrangement (28) form a continuous island.

5. A print head as claimed in claim 3, wherein the same doping is applied to the polysilicon layer to define the field relief region (20) and the heating portion.

6. A print head as claimed in 3, wherein the terminal portions (29) are also doped, with different doping to the heating portion.

7. A print head as claimed in claim 3, wherein the same doping is applied to the terminal portions (29) as to source and drain contact portions (22,24) of the drive transistor.

8. A print head as claimed in claim 1, wherein a metal contact layer (36) is provided which connects to the source and drain contact portions (22,24) and to the heating arrangement (28).

9. A print head as claimed in claim 8, wherein a heating chamber (44) is provided over the heater arrangement, and wherein the metal contact layer (90) extends into an area beneath the heating chamber (44), and wherein the heating arrangement comprises a polysilicon island with uniform doping.

10. A print head as claimed in claim 1, wherein the drive transistor has multiple field relief regions (100;110).

11. A print head as claimed in claim 10, wherein a field relief region (100) is provided adjacent each of the source (22) and drain (24) contact regions.

12. A print head as claimed in claim 10, wherein the field relief regions comprise multiple regions (110) of different doping adjacent the drain contact region (24).

13. A print head as claimed in claim 1, wherein the drive transistors are provided over a common substrate (10) and dielectric layer stack (12) and comprise in order from the substrate:
a polysilicon layer (14);
a gate dielectric layer (30);
a gate conductor layer (32);
an interlayer dielectric layer (34); and
source and drain connections defined by a second metal layer (36).

14. A print head as claimed in claim 13, wherein each print head heater circuit comprises a heater chamber (44) above the heater arrangement (28), the heater chamber being provided above the polysilicon layer (14), the gate dielectric layer (30), the interlayer dielectric layer (34) and a further dielectric layer (40).

15. A print head as claimed in claim 13, wherein each print head heater circuit comprises a heater chamber (44) above the heater arrangement (28), the heater chamber (44) being provided above the polysilicon layer (14) and the further dielectric layer (40), the gate dielectric layer (30) and the interlayer dielectric layer (34) being removed from beneath the heater chamber (44).

16. A print head as claimed in claim 14, wherein the chamber (44) is defined by chamber walls (50) and an overlying orifice plate (52).

17. A print head as claimed in claim 1, wherein the drive transistor comprises a non self-aligned thin film transistor.

18. A print head as claimed in claim 1, wherein the drive transistor comprises a self-aligned thin film transistor.

19. A method of fabricating an array of print head heater circuits for an inkjet print head, the circuits provided over a common substrate (30), the method comprising:
providing a dielectric layer (32) over the common substrate (30);
depositing an amorphous silicon layer over the dielectric layer (32);
processing the amorphous silicon layer to form polycrystalline portions;
providing a gate dielectric layer (50) over the doped polysilicon layer;
providing a gate conductor layer (52) over the gate dielectric layer and defining at least gate terminals from the gate conductor layer (52); and
providing a further dielectric layer (54),
wherein a plurality of doping operations are performed to define source, gate, drain and field relief transistor regions in the polysilicon portions, a field relief region being provided at least adjacent the drain transistor region beneath the gate, and wherein the heater arrangement comprises a portion of the polysilicon layer which defines the drive transistor channel.

20. A method as claimed in claim 19, further comprising providing a second metal layer (56) over the further dielectric layer (54) to define source and drain connections and connections to the heating arrangement.

21. A method as claimed in claim 19, wherein the doping operations further define doped heating arrangement terminal portions (29) and a heating portion between the terminal portions (29).

22. A method as claimed in claim 21, wherein the polysilicon of the transistor (16) and heater arrangement (28) are patterned as a continuous island.

23. A method as claimed in claim 21, wherein the same doping is applied to the polysilicon layer to define the field relief region (20) and the heating portion.

24. A method as claimed in 21, wherein the doping operations further dope the terminal portions (29) with different doping to the heating portion.

25. A method as claimed in claim 21, wherein the same doping is applied to the terminal portions (29) as to source and drain contact portions (22,24) of the transistor.

26. A method as claimed in 19, further comprising forming a heating chamber (44) over the heater arrangement, wherein the metal contact layer (90) extends into an area beneath the heating chamber (44), and wherein the heating arrangement comprises a polysilicon island with uniform doping.

27. A method as claimed in claim 19, wherein the doping operations define multiple field relief regions (100;110).

28. A method as claimed in claim 27, wherein the doping operations define a field relief region (100) adjacent each of the source (22) and drain (24).

29. A method as claimed in claim 27, wherein the doping operations define multiple field relief regions (110) of different doping adjacent the drain (24).
